(19) United States
(12) Patent Application Publication
(10) Pub. No.: US 2021/0114047 A1
(43) Pub. Date: Apr. 22, 2021

(54) FILM FORMING APPARATUS

(71) Applicant: Toshiba Mitsubishi-Electric Industrial Systems Corporation, Tokyo (JP)

(72) Inventor: Hiroyuki ORITA, Tokyo (JP)

(73) Assignee: Toshiba Mitsubishi-Electric Industrial Systems Corporation, Tokyo (JP)

(21) Appl. No.: 17/047,695

(22) PCT Filed: Jun. 8, 2018
(86) PCT No.: PCT/JP2018/022034

§ 371 Date: Oct. 15, 2020

(51) Int. Cl. B05B 7/16; B05B 13/02

(52) U.S. Cl. CPC B05B 7/1606; B05B 13/0221

(57) ABSTRACT

In a film forming apparatus of the first embodiment, an infrared radiation apparatus and a thin film forming nozzle are separately disposed from each other so that heating treatment performed in a heating chamber and mist spray treatment performed in a film forming chamber are not affected by each other. The film forming apparatus of the first embodiment performs the heating treatment of infrared radiation of the infrared radiation apparatus in the heating chamber and then performs the mist spray treatment of the thin film forming nozzle in the film forming chamber.

### TECHNICAL FIELD

The present invention relates to a film forming apparatus that is used to manufacture an electronic device such as a solar battery and that forms a film on a substrate.

### BACKGROUND ART

As a method of forming a film on a substrate, the chemical vapor deposition (CVD) method has been known. However, the chemical vapor deposition method often requires film formation in a vacuum, and thus a large vacuum chamber, as well as a vacuum pump etc., needs to be used. Further, in the chemical vapor deposition method, there has been a problem in that using a substrate having a large area as a substrate to be subjected to film formation is difficult from a point of view of costs or the like. In view of this, a misting method, which enables film forming treatment in atmospheric pressure, has been drawing attention.

As a conventional technology related to a film forming apparatus using such a misting method, for example, there is a technology according to Patent Document 1.

In the technology according to the Patent Document 1, atomized source solution and reaction material are sprayed from a source solution ejection port and a reaction material ejection port that are provided on a bottom surface of a mist spray head unit including a mist spray nozzle etc. to a substrate disposed in an atmosphere. With such spraying, a film is formed on the substrate. Note that the reaction material refers to a material that contributes to a reaction with the source solution.

FIG. 7 is an explanatory diagram illustrating a schematic configuration of a conventional film forming apparatus. As illustrated in FIG. 7, on the upper surface of a substrate placing stage 30 being a substrate placing unit, a plurality of substrates 10 are placed.

The substrate placing stage 30 includes a suction mechanism 31 that performs vacuum suction. Using the suction mechanism 31, the substrate placing stage 30 can suck the entire back surface of each of the plurality of placed substrates 10 onto the upper surface of the substrate placing stage 30. Further, in the substrate placing stage 30, a heating mechanism 32 is provided below the suction mechanism 31. Using the heating mechanism 32, the substrate placing stage 30 can perform heating treatment on the plurality of substrates 10 placed on the upper surface of the substrate placing stage 30.

A thin film forming nozzle 1 (mist spray unit) performs mist spray treatment of spraying source mist MT downwardly from a spray port provided in a spray surface 1S. Note that the source mist MT is a mist obtained by atomizing a source solution. Using the thin film forming nozzle 1, the source mist MT can be sprayed in the atmosphere.

All of the thin film forming nozzle 1, the substrate placing stage 30, and the plurality of substrates 10 placed on the upper surface of the substrate placing stage 30 are accommodated in a film forming chamber 60. The film forming chamber 60 includes an upper chamber 68, a lower chamber 69, and a door 67. When the film forming chamber 60 performs film forming treatment, the film forming chamber 60 can isolate the thin film forming nozzle 1, the substrate placing stage 30, and the plurality of substrates 10 from the outside by closing the door 67 to close an opening portion between the upper chamber 68 and the lower chamber 69.

Thus, by closing the door 67 of the film forming chamber 60 and performing mist spray treatment using the thin film forming nozzle 1 during the heating treatment of the heating mechanism 32, a thin film can be formed on the substrates 10 placed on the upper surface of the substrate placing stage 3.

In this manner, a conventional film forming apparatus forms a thin film on the substrates 10 by simultaneously performing mist spray treatment using the thin film forming nozzle 1 and heating treatment using the heating mechanism 32.

### PRIOR ART DOCUMENTS

### Patent Documents

Patent Document 1: WO 2017/068625 A1

### SUMMARY

### Problem to be Solved by the Invention

As described above, generally, a conventional film forming apparatus has the following configuration. Specifically, the heating mechanism 32 is provided inside the substrate placing stage 30 that allows the substrates 10, which are base materials as a target of film formation, to be placed on its upper surface, and the substrate placing stage 30 is used as a flat heating means.

When a flat heating means such as the substrate placing stage 30 is used, heating treatment for the substrates 10 is performed by bringing the upper surface of the substrate placing stage 30 and the lower surface of the substrates 10 to come in contact with each other and causing heat to be transferred between the substrate placing stage 30 and the substrates 10.

However, when the substrate 10 has such a structure that the lower surface of the substrate is curved or the lower surface has recessed portions and projecting portions, instead of having a flat plate-like shape, the flat heating means allows the upper surface of the substrate placing stage 30 and the back surface of the substrates 10 to only locally come in contact with each other. Therefore, there have been problems in that heating of the substrates 10 is uneven when heating treatment is performed by the heating mechanism 32, and the substrates 10 are warped and deformed, for example.

The present invention has an object to solve the problems as described above, and provide a film forming apparatus that can form a thin film on a substrate without reducing film forming quality and a film forming rate.

### Means to Solve the Problem

A film forming apparatus according to the present invention includes: a substrate conveying unit being configured to convey a substrate; a heating mechanism including an infrared lamp and being configured to perform heating treatment of heating the substrate by radiating infrared light from the infrared lamp; and a mist spray unit being configured to perform mist spray treatment of spraying source mist obtained by atomizing a source solution. The heating mechanism and the mist spray unit are separately disposed so that the heating treatment and the mist spray treatment are not affected by each other. A thin film is formed on a front surface of the substrate by performing the heating treatment with the heating mechanism and then performing the mist spray treatment with the mist spray unit while conveying the substrate with the substrate conveying unit.

### Effects of the Invention

The film forming apparatus of the invention of the present application according to claim 1 includes the heating mechanism that performs heating treatment of heating the substrate by radiating infrared light from the infrared lamp. Therefore, by performing the heating treatment of the heating mechanism, the substrate can be uniformly heated regardless of the shape of the substrate.

Further, the heating mechanism and the mist spray unit are separately disposed so that the heating treatment and the mist spray treatment are not affected by each other. Therefore, occurrence of a source mist evaporation phenomenon, in which a source mist absorbs infrared light to be heated and evaporated, can be securely avoided when each of the heating treatment and the mist spray treatment is performed.

As a result, by performing the heating treatment of the heating mechanism and then performing the mist spray treatment of the mist spray unit, the film forming apparatus of the invention of the present application according to claim 1 can form a thin film on the front surface of the substrate without reducing film forming quality and a film forming rate.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is an explanatory diagram illustrating a schematic configuration of a film forming apparatus according to a first embodiment of the present invention.

FIG. 2 is an explanatory diagram illustrating a schematic configuration of a film forming apparatus according to a second embodiment of the present invention.

FIG. 3 is an explanatory diagram schematically illustrating a first modification of the second embodiment.

FIG. 4 is an explanatory diagram schematically illustrating a second modification of the second embodiment.

FIG. 5 is an explanatory diagram (No. 1) illustrating a schematic configuration of a film forming apparatus according to a third embodiment of the present invention.

FIG. 6 is an explanatory diagram (No. 2) illustrating the schematic configuration of the film forming apparatus according to the third embodiment of the present invention.

FIG. 7 is an explanatory diagram illustrating a schematic configuration of a conventional film forming apparatus.

### DESCRIPTION OF EMBODIMENTS

<Basic Art>

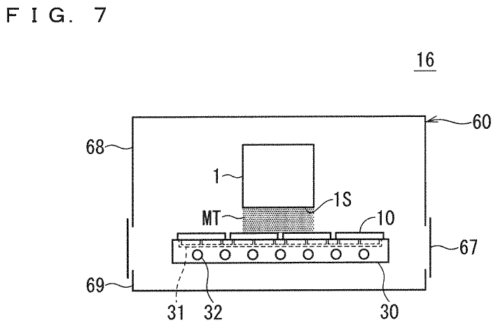

An improved configuration of the conventional technology illustrated in FIG. 7 is conceived as new basic art. In the improved configuration, an infrared radiation apparatus that performs heating treatment of heating the substrates 10 by radiating infrared light from the infrared lamps is separately provided as a heating mechanism and is disposed apart from the substrate placing stage 30, instead of a configuration in which the heating mechanism 32 is provided inside the substrate placing stage 30.

The basic art can perform direct heating with infrared light being electromagnetic waves without coming into contact with the substrates 10 as a base material by using the infrared radiation apparatus as the heating mechanism, and can thus perform uniform heating regardless of the shape of the substrates 10.

Even in the basic art, however, a source mist evaporation phenomenon, in which a source mist MT absorbs infrared light radiated from the infrared radiation apparatus so that the source mist MT is heated and evaporated, occurs, and thus there remain problems of deterioration in film forming quality and a film forming rate. Further, the source mist evaporation phenomenon also has a problem of hindering heating treatment performed by the infrared radiation apparatus.

The first embodiment to the third embodiment to be described below have an object of comprehensively solving the problems of the conventional technology and the basic art described above.

### First Embodiment

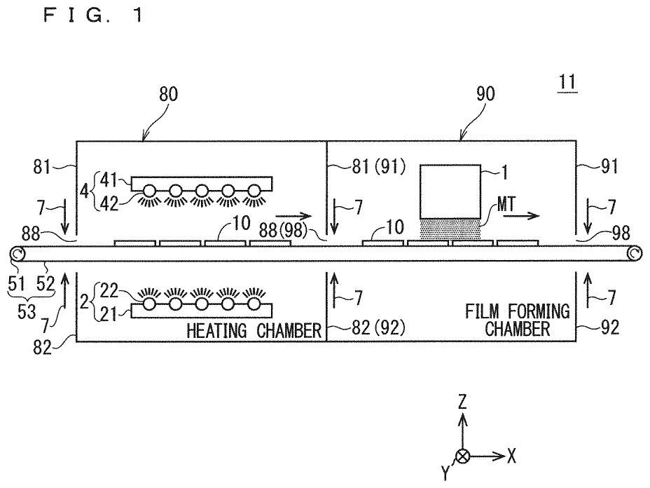

FIG. 1 is an explanatory diagram illustrating a schematic configuration of a film forming apparatus according to the first embodiment of the present invention. An XYZ orthogonal coordinate system is illustrated in FIG. 1.

As illustrated in FIG. 1, a film forming apparatus 11 of the first embodiment includes a heating chamber 80, a film forming chamber 90, a thin film forming nozzle 1, infrared radiation apparatuses 2 and 4, and a conveyor 53 as main components.

The conveyor 53 being a substrate conveying unit allows the plurality of substrates 10 to be placed on the upper surface of the belt 52, and conveys the plurality of substrates 10 in a conveying direction (X direction). The conveyor 53 includes a pair of rollers 51 for conveyance provided at both right and left (−X direction, +X direction) ends, and an endless belt 52 for conveyance that is stretched across the pair of rollers 51. Note that the belt 52 includes a combination of a pair of linear conveyor chains provided at both ends in the Y direction.

With rotational drive of the pair of rollers 51, the conveyor 53 can move an upper side (+Z direction side) of the belt 52 along the conveying direction (X direction).

Of the pair of rollers 51 of the conveyor 53, one roller is provided on the left side (−X direction) outside the heating chamber 80, and the other roller is provided on the right side (+X direction) outside the film forming chamber 90. Further, a center portion of the belt 52 is provided inside any of the heating chamber 80 and the film forming chamber 90.

With rotational drive of the pair of rollers 51, the belt 52 can be moved between the inside of the heating chamber 80 and the inside and the outside of the film forming chamber 90 through a pair of opening portions 88 provided at a portion of right and left (−X direction, +X direction) side surfaces of the heating chamber 80 and a pair of opening portions 98 provided at a portion of right and left side surfaces of the film forming chamber 90.

The heating chamber 80 and the film forming chamber 90 are adjacently provided, and the right opening portion 88 of the heating chamber 80 and the left opening portion 98 of the film forming chamber 90 are shared.

A part of the conveyor 53 and the infrared radiation apparatuses 2 and 4 are accommodated in the heating chamber 80. The heating chamber 80 includes an upper chamber 81, a lower chamber 82, and a pair of opening portions 88. The pair of opening portions 88 is located between the upper chamber 81 and the lower chamber 82 in a height direction being the Z direction. Therefore, the conveyor 53 provided between the opening portions 88 and 88 in the heating chamber 80 is disposed at a position higher than the lower chamber 82 and lower than the upper chamber 81.

The infrared radiation apparatus 2 being a first direction heating unit is fixed at a position apart from the conveyor 53 inside the lower chamber 82 by a fixing means (not shown). The infrared radiation apparatus 4 being a second direction heating unit is fixed at a position apart from the conveyor 53 inside the upper chamber 81 by a fixing means (not shown). The combination of the infrared radiation apparatus 2 and the infrared radiation apparatus 4 constitutes a heating mechanism.

Note that both of the infrared radiation apparatuses 2 and 4 are disposed at positions overlapping an upper surface area (area interposed between the pair of linear conveyor chains) of the belt 52 in the heating chamber 80 in plan view.

The infrared radiation apparatus 2 includes a lamp placing table 21 and a plurality of infrared lamps 22. The plurality of infrared lamps 22 are attached to an upper portion of the lamp placing table 21. Therefore, the infrared radiation apparatus 2 can radiate infrared light upwardly (+Z direction) from the plurality of infrared lamps 22. With the above-mentioned infrared radiation of the infrared radiation apparatus 2, heating treatment (first direction heating treatment) for the plurality of substrates 10 placed on the upper surface of the belt 52 can be performed.

The infrared radiation apparatus 4 includes a lamp placing table 41 and a plurality of infrared lamps 42. The plurality of infrared lamps 42 are attached to a lower portion of the lamp placing table 41. Therefore, the infrared radiation apparatus 4 can radiate infrared light downwardly (−Z direction) from the plurality of infrared lamps 42. With the above-mentioned infrared radiation of the infrared radiation apparatus 4, heating treatment (second direction heating treatment) for the plurality of substrates 10 placed on the upper surface of the belt 52 can be performed.

In this manner, the infrared radiation apparatus 2 being a first direction heating unit performs first direction heating treatment of heating the plurality of substrates 10 by radiating infrared light toward the +Z direction (first direction). The +Z direction is a direction from the back surface toward the front surface of the substrates 10.

In contrast, the infrared radiation apparatus 4 being a second direction heating unit performs second direction heating treatment of heating the plurality of substrates 10 by radiating infrared light toward the −Z direction (second direction) being a direction opposite to the +Z direction. The −Z direction is a direction from the front surface to the back surface of the substrates 10.

Further, the film forming apparatus 11 includes the heating chamber 80 that internally accommodates the substrates 10 and the infrared radiation apparatuses 2 and 4, when the film forming apparatus 11 performs heating treatment (first direction heating treatment and second direction heating treatment) performed by the infrared radiation apparatuses 2 and 4.

The heating chamber 80 can isolate the plurality of substrates 10 placed on the belt 52 and the infrared radiation apparatuses 2 and 4 from the outside by closing the opening portions 88 between the upper chamber 81 and the lower chamber 82 with an air curtain 7 when heating treatment is performed.

The thin film forming nozzle 1 and a part of the conveyor 53 are accommodated in the film forming chamber 90. The film forming chamber 90 includes an upper chamber 91, a lower chamber 92, and a pair of opening portions 98. The pair of opening portions 98 is located between the upper chamber 91 and the lower chamber 92 in the height direction being the Z direction. Therefore, the conveyor 53 provided between the opening portions 98 and 98 in the film forming chamber 90 is disposed at a position higher than the lower chamber 92 and lower than the upper chamber 91.

The thin film forming nozzle 1 being a mist spray unit is fixedly disposed in the upper chamber 91 by a fixing means (not shown). In this case, the thin film forming nozzle 1 is disposed to have such a positional relationship that the spray surface 1S and the upper surface of the belt 52 face each other.

The thin film forming nozzle 1 performs mist spray treatment of spraying source mist MT downwardly (−Z direction) from a spray port provided in the spray surface 1S. Note that the source mist MT is a mist obtained by atomizing a source solution. Using the thin film forming nozzle 1, the source mist MT can be sprayed in the atmosphere.

The film forming chamber 90 can isolate the thin film forming nozzle 1 and the plurality of substrates 10 placed on the belt 52 from the outside by closing the opening portions 98 between the upper chamber 91 and the lower chamber 92 with the air curtain 7 when mist spray treatment is performed.

Therefore, the film forming apparatus 11 of the first embodiment can set a film forming environment by closing both of the pair of opening portions 88 of the heating chamber 80 and the pair of opening portions 98 of the film forming chamber 90 with the air curtain 7 and moving the belt 52 of the conveyor 53 along the conveying direction (X direction).

In the film forming apparatus 11 of the first embodiment, under the film forming environment, the infrared radiation apparatuses 2 and 4 and the thin film forming nozzle 1 are disposed separately from each other, so that the heating treatment performed in the heating chamber 80 and the mist spray treatment performed in the film forming chamber 90 are not affected by each other.

Then, in the film forming apparatus 11 of the first embodiment, under the film forming environment, the heating treatment of infrared radiation of the infrared radiation apparatuses 2 and 4 is performed in the heating chamber 80, and subsequently, the mist spray treatment of the thin film forming nozzle 1 is performed in the film forming chamber 90.

As a result, the film forming apparatus 11 of the first embodiment can form a thin film on front surfaces of the substrates 10 placed on the upper surface of the belt 52 in the film forming chamber 90.

As described above, the film forming apparatus 11 of the first embodiment includes a combination of the infrared radiation apparatuses 2 and 4 that are provided apart from the conveyor 53 being a substrate conveying unit and perform heating treatment of heating the plurality of substrates 10 by radiating infrared light from the infrared lamps 22 and 42 as a heating mechanism.

Thus, the film forming apparatus 11 of the first embodiment can heat the substrates 10 with the infrared radiation apparatuses 2 and 4 without touching the substrates 10. Therefore, the film forming apparatus 11 of the first embodiment can perform uniform heating without deforming the substrates 10, regardless of the shape of the substrates 10.

Further, the infrared radiation apparatuses 2 and 4 and the thin film forming nozzle 1 are disposed separately from each other so that the heating treatment and the mist spray treatment are not affected by each other. Therefore, occurrence of the source mist evaporation phenomenon, in which a source mist absorbs infrared light to be heated and evaporated, can be securely avoided when each of the heating treatment and the mist spray treatment is performed.

As a result, the film forming apparatus 11 of the first embodiment can form a thin film on the substrates 10 without reducing film forming quality and a film forming rate.

In addition, as the heating treatment performed in the heating chamber 80, the first direction heating treatment performed by the infrared radiation apparatus 2 and the second direction heating treatment performed by the infrared radiation apparatus 4 are simultaneously performed. This enables heating from the back surface of the substrates 10 in the first direction heating treatment and heating from the front surface of the substrates 10 in the second direction heating treatment.

As a result, the film forming apparatus 11 of the first embodiment can more uniformly heat the substrates 10 in the heating chamber 80.

Further, by providing the infrared radiation apparatuses 2 and 4 being a heating mechanism inside the heating chamber 80, the film forming apparatus 11 of the first embodiment can radiate infrared light on the substrates 10 without through the heating chamber 80. Accordingly, the film forming apparatus 11 of the first embodiment can enhance efficiency of radiating infrared light.

Note that the radiation of infrared light from the infrared radiation apparatus 2 located below (−Z direction) the conveyor 53 is performed upwardly (+Z direction). This means that infrared light is radiated on the plurality of substrates 10 through the belt 52 (upper side and lower side) of the conveyor 53.

In consideration of such configurations, the first countermeasure and the second countermeasure are conceivable. The first countermeasure adopts a structure in which the belt 52 includes a combination of a pair of linear conveyor chains and an opening portion for transmission of infrared light is provided, and the second countermeasure adopts a configuration in which an infrared light transmitting material having excellent transmittance of infrared light that does not absorb infrared light is used as a constituent material of the belt 52.

Thus, regarding the belt 52, by adopting at least one countermeasure out of the first and second countermeasures, an infrared light absorption degree of the belt 52 can be reduced to a minimum necessary degree.

A specific example of the second countermeasure will be described below. Possible examples of the infrared light transmitting material include germanium, silicon, zinc sulfide, and zinc selenide. Note that it is necessary that strength for being used as the belt 52 be satisfied.

In contrast, radiation of infrared light from the infrared radiation apparatus 4 located above (+Z direction) the conveyor 53 is performed downwardly (−Z direction), and the infrared light is directly radiated on the substrates 10. Thus, the first and second countermeasures described above need not be taken into consideration.

### Second Embodiment

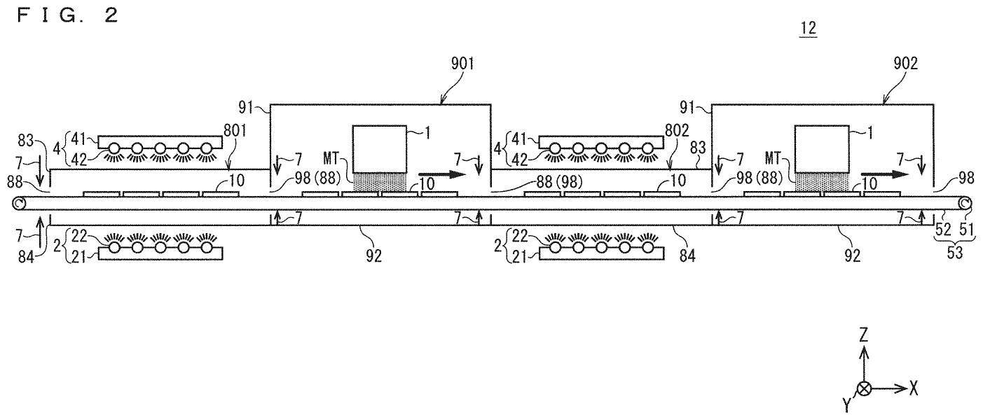

FIG. 2 is an explanatory diagram illustrating a schematic configuration of a film forming apparatus according to the second embodiment of the present invention. An XYZ orthogonal coordinate system is illustrated in FIG. 2.

As illustrated in FIG. 2, a film forming apparatus 12 of the second embodiment includes heating chambers 801 and 802, film forming chambers 901 and 902, two thin film forming nozzles 1, a combination of two pairs of infrared radiation apparatuses 2 and 4, and a conveyor 53 as main components.

The conveyor 53 being a substrate conveying unit allows the plurality of substrates 10 to be placed on the upper surface of the belt 52, and conveys the plurality of substrates 10 in the conveying direction (X direction). The conveyor 53 includes a pair of rollers 51 for conveyance provided at both right and left ends, and an endless belt 52 for conveyance that is stretched across the pair of rollers 51.

With rotational drive of the pair of rollers 51, the conveyor 53 can move an upper side (+Z direction side) of the belt 52 along the conveying direction (X direction).

Of the pair of rollers 51 of the conveyor 53, one roller is provided on the left side (−X direction) outside the heating chamber 801, and the other roller is provided on the right side (+X direction) of the film forming chamber 902. Further, a center portion of the belt 52 is provided inside any of the heating chamber 801, the heating chamber 802, the film forming chamber 901, and the film forming chamber 902.

Therefore, with rotational drive of the pair of rollers 51, the belt 52 can be moved between the inside of the heating chambers 801 and 802 and the inside and the outside of the film forming chambers 901 and 902 through a pair of opening portions 88 provided at a portion of respective right and left (−X direction, +X direction) side surfaces of the heating chambers 801 and 802 and a pair of opening portions 98 provided at a portion of respective right and left side surfaces of the film forming chambers 901 and 902.

The heating chambers 801 and 802 and the film forming chambers 901 and 902 are adjacently provided from the left side to the right side in the order of the heating chamber 801, the film forming chamber 901, the heating chamber 802, and the film forming chamber 902. Further, the right opening portion 88 of the heating chamber 801 and the left opening portion 98 of the film forming chamber 901 are shared. The right opening portion 98 of the film forming chamber 901 and the left opening portion 88 of the heating chamber 802 are shared. The right opening portion 88 of the heating chamber 802 and the opening portion 98 of the film forming chamber 902 are shared.

A part of the conveyor 53 is accommodated in the heating chambers 801 and 802. The configuration inside and around the heating chambers 801 and 802 are the same, and thus the heating chamber 801 will be mainly described below.

The heating chamber 801 includes an upper chamber 83, a lower chamber 84, and a pair of opening portions 88. The pair of opening portions 88 is located between the upper chamber 83 and the lower chamber 84 in the height direction being the Z direction. Therefore, the conveyor 53 provided between the opening portions 88 and 88 in the heating chamber 801 is disposed at a position higher than the lower chamber 84 and lower than the upper chamber 83.

In an area around the heating chamber 801, the infrared radiation apparatus 2 being a first direction heating unit is fixed at a position apart from the conveyor 53 on a lower side (−Z direction) outside the lower chamber 84 by a fixing means (not shown).

In an area around the heating chamber 801, the infrared radiation apparatus 4 being a second direction heating unit is fixed at a position apart from the conveyor 53 on an upper side (+Z direction) outside the upper chamber 83 by a fixing means (not shown). The infrared radiation apparatus 2 and the infrared radiation apparatus 4 constitute a heating mechanism.

Note that both of the infrared radiation apparatuses 2 and 4 are disposed at positions overlapping an upper surface area (area interposed between the pair of linear conveyor chains) of the belt 52 in the heating chamber 801 in plan view.

Each of the heating chambers 801 and 802 uses, as its constituent material, an infrared light transmitting material having excellent transmittance that does not absorb infrared light radiated from the infrared radiation apparatuses 2 and 4. Specifically, each of the heating chambers 801 and 802 uses quartz glass as its constituent material.

The infrared radiation apparatus 2 being a first direction heating unit performs first direction heating treatment of heating the substrates 10 by radiating infrared light toward the +Z direction (first direction), similarly to the first embodiment.

The infrared radiation apparatus 4 being a second direction heating unit performs second direction heating treatment of heating the substrates 10 by radiating infrared light toward the −Z direction (second direction) being a direction opposite to the +Z direction, similarly to the first embodiment.

Further, the heating chamber 801 internally accommodates the substrates 10, when the heating treatment (first direction heating treatment and second direction heating treatment) of the infrared radiation apparatuses 2 and 4 is performed.

The heating chamber 801 can isolate the plurality of substrates 10 placed on the belt 52 from the outside by closing the opening portions 88 between the upper chamber 83 and the lower chamber 84 with the air curtain 7 when heating treatment is performed.

As described above, the film forming apparatus 12 of the second embodiment includes the infrared radiation apparatuses 2 and 4 provided in outer periphery of the heating chamber 801 as a first heating mechanism, and the infrared radiation apparatuses 2 and 4 provided in outer periphery of the heating apparatus 802 as a second heating mechanism.

Further, first heating treatment is performed by the infrared radiation apparatuses 2 and 4 for the plurality of substrates 10 in the heating chamber 801, and second heating treatment is performed by the infrared radiation apparatuses 2 and 4 for the plurality of substrates 10 in the heating chamber 802. These first and second heating treatments include the first direction heating treatment and the second direction heating treatment described above, respectively.

Each of the film forming chambers 901 and 902 accommodates the thin film forming nozzle 1 and a part of the conveyor 53. The internal configurations of the film forming chambers 901 and 902 are the same, and thus the film forming chamber 901 will be mainly described below.

The heating chamber 901 includes an upper chamber 91, a lower chamber 92, and a pair of opening portions 98. The pair of opening portions 98 is located between the upper chamber 91 and the lower chamber 92 in the height direction being the Z direction. Therefore, the conveyor 53 provided between the opening portions 98 and 98 in the film forming chamber 901 is disposed at a position higher than the lower chamber 4 and lower than the upper chamber 83.

In the film forming chamber 901, the thin film forming nozzle 1 being a mist spray unit is fixedly disposed in the upper chamber 91 by a fixing means (not shown). In this case, the thin film forming nozzle 1 is disposed to have such a positional relationship that the spray surface 1S and the upper surface of the belt 52 face each other.

In the film forming chamber 901, the thin film forming nozzle 1 performs mist spraying treatment of spraying source mist MT downwardly (−Z direction) from a spray port provided in the spray surface 1S, similarly to the first embodiment.

As described above, the film forming apparatus 12 of the second embodiment includes the thin film forming nozzle 1 provided in the film forming chamber 901 as a first mist spray unit, and the thin film forming nozzle 1 provided in the film forming chamber 902 as a second mist spray unit.

Further, first mist spraying treatment is performed by the thin film forming nozzle 1 provided in the film forming chamber 901, and second mist spraying treatment is performed by the thin film forming nozzle 1 provided in the film forming chamber 902.

Each of the film forming chambers 901 and 902 can isolate the thin film forming nozzle 1 and the plurality of substrates 10 placed on the belt 52 from the outside by closing the opening portions 98 between the upper chamber 91 and the lower chamber 92 with the air curtain 7 when mist spraying treatment is performed.

Therefore, the film forming apparatus 12 of the first embodiment can set a film forming environment by closing all of the pair of opening portions 88 of respective heating chambers 801 and 802 and the pair of opening portions 98 of respective film forming chambers 901 and 902 with the air curtain 7 and moving the belt 52 of the conveyor 53 along the conveying direction (X direction).

In the film forming apparatus 12 of the second embodiment, under the film forming environment, the combination of the two pairs of infrared radiation apparatuses 2 and 4 and the two thin film forming nozzles 1 are disposed separately from each other, so that the heating treatment performed for the substrates 10 in the heating chambers 801 and 802 and the mist spraying treatment performed in the film forming chambers 901 and 902 are not affected by each other.

Then, in the film forming apparatus 12 of the second embodiment, under the film forming environment, the first heating treatment of infrared radiation of the infrared radiation apparatuses 2 and 4 is performed for the plurality of substrates 10 in the heating chamber 801, and subsequently, the first mist spraying treatment of the thin film forming nozzle 1 is performed in the film forming chamber 901.

After that, in the film forming apparatus 12, under the film forming environment, the second heating treatment of infrared radiation of the infrared radiation apparatuses 2 and 4 is performed for the plurality of substrates 10 in the heating chamber 802, and subsequently, the second mist spraying treatment of the thin film forming nozzle 1 is performed in the film forming chamber 902.

As a result, the film forming apparatus 12 of the second embodiment can finally form a thin film on front surfaces of the substrates 10 placed on the upper surface of the belt 52 in the film forming chamber 902.

As described above, similarly to the first embodiment, the film forming apparatus 12 of the second embodiment can heat the substrates 10 with the combination of the two pairs of infrared radiation apparatuses 2 and 4 without touching the substrates 10. Therefore, the film forming apparatus 12 of the second embodiment can perform uniform heating without deforming the substrates 10, regardless of the shape of the substrates 10.

Further, similarly to the first embodiment, in the film forming apparatus 12 of the second embodiment, the two pairs of infrared radiation apparatuses 2 and 4 and the two thin film forming nozzles 1 are disposed separately from each other, so that the heating treatment and the mist spraying treatment are not affected by each other. Therefore, the film forming apparatus 12 can securely avoid occurrence of the source mist evaporation phenomenon, when each of the first and second heating treatments and the first and second mist spraying treatments is performed.

As a result, similarly to the first embodiment, the film forming apparatus 12 of the second embodiment can form a thin film on front surfaces of the substrates 10 without reducing film forming quality and a film forming rate.

As described above, in the film forming apparatus 12 of the second embodiment, the first and second heating mechanisms and the first and second mist spray units are alternately disposed in the order of the first mechanism/unit and the second mechanism/unit, so that the first and second heating treatments and the first and second mist spraying treatments are not affected by each other.

Further, the film forming apparatus 12 of the second embodiment has a feature in that the first and second heating treatments and the first and second mist spraying treatments are alternately performed in the order of the first treatment and the second treatment.

Therefore, the film forming apparatus 12 of the second embodiment can increase the thickness of a formed thin film, and can form thin films of a stacking structure including two films having different film qualities, by alternately repeatedly performing the heating treatment and the mist spraying treatment twice.

Note that, in the film forming apparatus 12 described above, a combination of two heating mechanisms and two mist spray units is illustrated. However, an extended modification, which is achieved by a combination of n (n≥2) heating mechanisms and n mist spray units, can be implemented.

The extended modification includes first to n-th heating mechanisms that perform first to n-th heating treatments, and first to n-th mist spray units that perform first to n-th mist spraying treatments.

In the extended modification, the first to n-th heating mechanisms and the first to n-th mist spray units are alternately disposed separately from each other in the order of the first mechanism/unit to the n-th mechanism/unit, so that the first to n-th heating treatments and the first to n-th mist spraying treatments are not affected by each other.

Further, the extended modification has a feature in that the first to n-th heating treatments and the first to n-th mist spraying treatments are alternately performed in the order of the first, second, . . . , n-th treatments.

Therefore, the extended modification can increase the thickness of a formed thin film, and can form thin films of a stacking structure including films of n layers having different film qualities, by alternately repeatedly performing the heating treatment and the mist spraying treatment n (≥2) times.

In addition, the film forming apparatus 12 of the second embodiment simultaneously performs the first direction heating treatment of the infrared radiation apparatus 2 and the second direction heating treatment of the infrared radiation apparatus 4 as the first and second heating treatments performed for the substrates 10 in the heating chambers 801 and 802, similarly to the first embodiment.

As a result, the film forming apparatus 12 of the second embodiment can more uniformly heat the substrates 10 in each of the heating chambers 801 and 802, similarly to the first embodiment.

Further, by providing the infrared radiation apparatuses 2 and 4 being a heating mechanism outside the heating chambers 801 and 802, the film forming apparatus 12 of the second embodiment can simplify maintenance of the infrared radiation apparatuses 2 and 4, such as replacement of the infrared lamps 22 and 42.

In addition, the heating chambers 801 and 802 of the film forming apparatus 12 of the second embodiment has, as its constituent material, quartz, glass being an infrared light transmitting material having excellent transmittance for infrared light radiated from the infrared lamps 22 and 42.

This configuration produces an effect of reducing an infrared light absorption degree of the bottom surface of the lower chamber 62 at the time of heating the substrates 10 through the bottom surface of the lower chamber 84 of each of the heating chambers 801 and 802 in the first direction heating treatment to a minimum necessary degree. In a similar manner, the configuration produces an effect of reducing an infrared light absorption degree of the upper surface of the upper chamber 83 at the time of heating the substrates 10 through the upper surface of the upper chamber 83 of each of the heating chambers 801 and 802 in the second direction heating treatment to a minimum necessary degree.

Further, other than quartz glass, possible examples of the infrared light transmitting material include germanium, silicon, zinc sulfide, and zinc selenide.

Note that, also in the film forming apparatus 12 of the second embodiment, similarly to the first embodiment, at least one countermeasure out of the first and second countermeasures related to infrared light absorption of the belt 52 may be adopted.

(Modifications)

As modifications of the second embodiment, the following configurations are conceivable. In the modifications, at least one configuration out of the first configuration and the second configuration is set: In the first configuration, a plurality of heating mechanisms each being a combination of the infrared radiation apparatuses 2 and 4 are present, and in the second configuration, a plurality of mist spray units each being the thin film forming nozzle 1 are present.

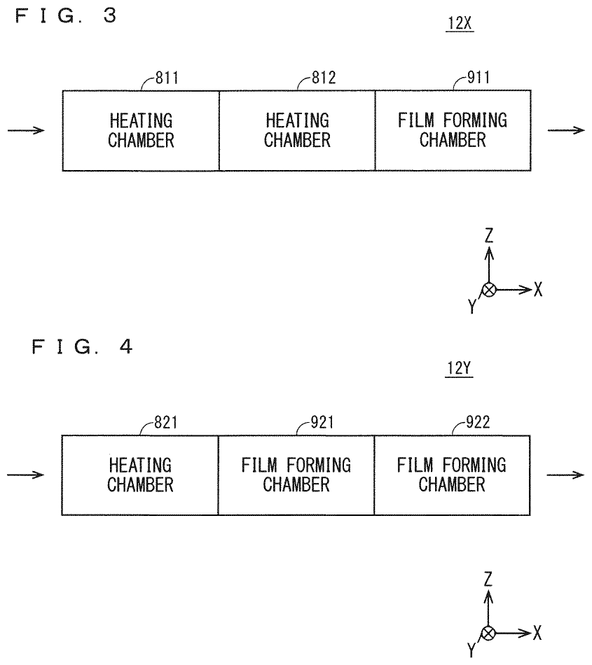

FIG. 3 is an explanatory diagram schematically illustrating a first modification of the second embodiment. An XYZ orthogonal coordinate system is illustrated in FIG. 3. As illustrated in FIG. 3, a heating chamber 811, a heating chamber 812, and a film forming chamber 911 are adjacently disposed in this order along the conveying direction, constituting a film forming apparatus 12X being the first modification of the second embodiment. Specifically, in the film forming apparatus 12X, the first configuration is set.

Note that, although not illustrated in FIG. 3, similarly to the heating chambers 801 and 802, the heating chambers 811 and 812 internally include a part of the conveyor 53 and include the infrared radiation apparatuses 2 and 4 in outer periphery, and similarly to the film forming chamber 901, the film forming chamber 911 internally includes a part of the conveyor 53 and the thin film forming nozzle 1. Further, the conveying direction of the substrates 10 with the conveyor 53 is from left to right.

In the film forming apparatus 12X being the first modification of the second embodiment, the first configuration is set. Thus, the film forming apparatus 12X produces an effect of relatively easily performing temperature setting of the substrates 10 by consecutively performing heating treatment twice on the substrates 10 in the heating chambers 811 and 812 without performing mist spray treatment in-between.

Note that, in the example illustrated in FIG. 3, heating treatment is performed twice consecutively without performing mist spray treatment in-between. However, it is conceivable to adopt an extended configuration in which heating treatment is performed three or more times consecutively without performing mist spray treatment in-between. Specifically, it is conceivable to adopt an extended configuration in which heating treatment is performed consecutively without performing mist spray treatment in-between by at least two heating mechanisms. In this case, it is expected that the above effect of the film forming apparatus 12X be enhanced.

FIG. 4 is an explanatory diagram schematically illustrating a second modification of the second embodiment. An XYZ orthogonal coordinate system is illustrated in FIG. 4. As illustrated in FIG. 4, a heating chamber 821 and film forming chambers 921 and 922 are adjacently disposed in this order along the conveying direction, constituting a film forming apparatus 12Y being the second modification of the second embodiment. Specifically, in the film forming apparatus 12Y, the second configuration is set.

Note that, although not illustrated in FIG. 4, similarly to the heating chamber 801, the heating chamber 821 internally includes a part of the conveyor 53 and includes the infrared radiation apparatuses 2 and 4 in outer periphery, and similarly to the film forming chambers 901 and 902, the film forming chambers 921 and 922 internally include a part of the conveyor 53 and the thin film forming nozzle 1. Further, the conveying direction of the substrates 10 is from left to right.

In the film forming apparatus 12Y being the second modification of the second embodiment, the second configuration is set. Thus, the film forming apparatus 12Y produces an effect of forming thin films of a stacking structure, which are formed under an environment in which temperatures of the substrates 10 are different, by consecutively performing mist spray treatment twice in the film forming chambers 921 and 922 without performing heating treatment in-between.

Note that, in the example illustrated in FIG. 4, mist spray treatment is performed twice consecutively without performing heating treatment in-between. However, it is conceivable to adopt an extended configuration in which heating treatment is performed three or more times consecutively without performing heating treatment in-between. Specifically, it is conceivable to adopt an extended configuration in which mist spray treatment is consecutively performed without performing heating treatment in-between by at least two mist spray units. In this case, it is expected that the above effect of the film forming apparatus 12Y be enhanced.

Further, as a third modification of the second embodiment, both the first configuration and the second configuration may be set, and a film forming apparatus in which the heating chambers 811 and 812 of the film forming apparatus 12X and the film forming chambers 921 and 922 of the film forming apparatus 12Y are combined may be implemented.

### Third Embodiment

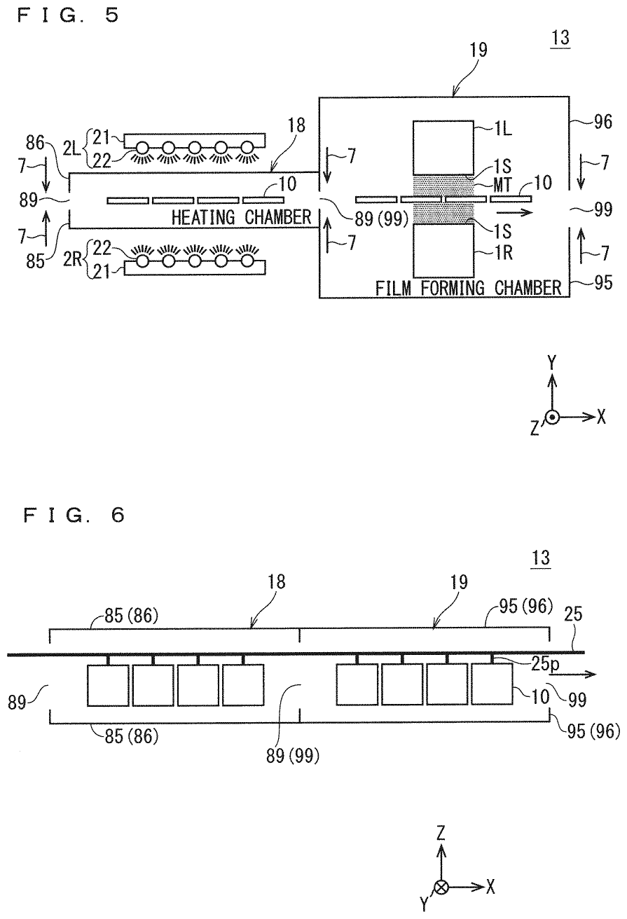

FIG. 5 and FIG. 6 are each an explanatory diagram illustrating a schematic configuration of a film forming apparatus according to the third embodiment of the present invention. FIG. 5 illustrates a configuration seen from the above, and FIG. 6 illustrates a configuration seen from a side surface similarly to FIG. 1 and FIG. 2. An XYZ orthogonal coordinate system is illustrated in each of FIG. 5 and FIG. 6.

As illustrated in FIG. 5 and FIG. 6, a film forming apparatus 13 of the third embodiment includes a heating chamber 18, a film forming chamber 19, a combination of thin film forming nozzles 1R and 1L, a combination of infrared radiation apparatuses 2R and 2L, and a conveyor chain 25 as main components. Note, in FIG. 5, illustration of the conveyor chain 25 is omitted, and in FIG. 6, illustration of the infrared radiation apparatuses 2R and 2L and the thin film forming nozzles 1R and 1L is omitted.

As illustrated in FIG. 6, the conveyor chain 25 being a substrate conveying unit includes substrate suspending parts 25p, and suspends the plurality of substrates 10 by using the substrate suspending parts 25p. In this case, the plurality of substrates 10 are suspended so that the left side (+Y direction side) corresponds to a front surface and the right side (−Y direction side) corresponds to a back surface with respect to the conveying direction (+X direction).

The conveyor chain 25 can be moved in the conveying direction (X direction) by a driving means (not shown), and can move the plurality of substrates 10 in the conveying direction along with movement of the conveyor chain 25.

One end of the conveyor chain 25 is provided on the left side (−X direction) outside the heating chamber 18, and another end is provided on the right side (+X direction) outside the film forming chamber 19.

Further, a center portion of the conveyor chain 25 is provided inside any of the heating chamber 18 and the film forming chamber 19, and can be moved between the inside of the heating chamber 18 and the inside and the outside of the film forming chamber 19 through the pair of opening portions 89 provided at a portion of right and left (−X direction, +X direction) side surfaces of the heating chamber 18 and the opening portions 99 provided on right and left side surfaces of the film forming chamber 19.

The heating chamber 18 and the film forming chamber 19 are adjacently provided from left to right in the order of the heating chamber 18 and the film forming chamber 19. Further, the right opening portions 89 of the heating chamber 18 and left opening portions 99 of the film forming chamber 19 are shared.

A part of the conveyor chain 25 is accommodated inside the heating chamber 18. The heating chamber 18 includes a right chamber 85, a left chamber 86, and a pair of opening portions 89. The pair of opening portions 89 is located between the right chamber 85 and the left chamber 86 in a width direction being the Y direction. Therefore, the conveyor chain 25 provided between the opening portions 89 and 89 in the heating chamber 18 is disposed on the left side (+Y direction side) of the right chamber 85 and the right side (−Y direction side) of the left chamber 86, with respect to the conveying direction (X direction).

The heating chamber 18 has, as its constituent material, an infrared light transmitting material having excellent transmittance that does not absorb infrared light radiated from the infrared radiation apparatuses 2R and 2L. Specifically, the heating chamber 18 adopts quartz glass as its constituent material. Other than quartz glass, possible examples of the infrared light transmitting material include germanium, silicon, zinc sulfide, and zinc selenide.

The infrared radiation apparatus 2R being a first direction heating unit is fixed to the right side (−Y direction) outside the right chamber 85 by a fixing means (not shown), with respect to the conveying direction (+X direction). Thus, the infrared radiation apparatus 2R is disposed apart from the conveyor chain 25.

The infrared radiation apparatus 2L being a second direction heating unit is fixed to the left side (+Y direction) outside the left chamber 86 by a fixing means (not shown), with respect to the conveying direction. Thus, the infrared radiation apparatus 2L is disposed apart from the conveyor chain 25. The combination of the infrared radiation apparatus 2R and the infrared radiation apparatus 2L constitutes a heating mechanism.

Note that, although not illustrated in FIG. 4, both the infrared radiation apparatuses 2R and 2L are disposed at height substantially the same as that of the plurality of substrates 10 in the heating chamber 18.

The infrared radiation apparatus 2R being a first direction heating unit performs first direction heating treatment of heating the substrates 10 by radiating infrared light toward the +Y direction (first direction). The +Y direction being the left side with respect to the conveying direction is a direction from the back surface toward the front surface of the substrates 10.

The infrared radiation apparatus 2L being a second direction heating unit performs second direction heating treatment of heating the substrates 10 by radiating infrared light toward the −Y direction (second direction) being a direction opposite to the +Y direction. The −Y direction being the right side with respect to the conveying direction is a direction from the front surface toward the back surface of the substrates 10.

Further, the heating chamber 18 internally accommodates the substrates 10, when the heating treatment (first direction heating treatment and second direction heating treatment) of the infrared radiation apparatuses 2R and 2L is performed.

When the heating chamber 18 performs heating treatment, the heating chamber 18 can isolate the plurality of substrates 10 suspended by the substrate suspending parts 25p from the outside by closing the opening portions 89 between the right chamber 85 and the left chamber 86 with the air curtain 7.

In this manner, the film forming apparatus 13 of the third embodiment includes the infrared radiation apparatuses 2R and 2L provided in outer periphery of the heating chamber 18 as a heating mechanism.

Further, heating treatment is performed by the infrared radiation apparatuses 2R and 2L provided in outer periphery of the heating chamber 18.

The film forming chamber 19 accommodates the thin film forming nozzles 1R and 1L and a part of the conveyor chain 25. The film forming chamber 19 includes a right chamber 95, a left chamber 96, and a pair of opening portions 99. The pair of opening portions 99 is located between the right chamber 95 and the left chamber 96 in the width direction being the Y direction. Therefore, the conveyor chain 25 provided between the opening portions 99 and 99 in the film forming chamber 19 is disposed on the left side of the right chamber 95 and the right side of the left chamber 96, with respect to the conveying direction.

The thin film forming nozzle 1R being a first direction mist spray unit is fixedly disposed inside the right chamber 95 by a fixing means (not shown). In this case, the thin film forming nozzle 1R is disposed to have such a positional relationship that the spray surface 1S and the back surface of the substrates 10 face each other.

The thin film forming nozzle 1L being a second direction mist spray unit is fixedly disposed inside the left chamber 96 by a fixing means (not shown). In this case, the thin film forming nozzle 1L is disposed to have such a positional relationship that the spray surface 1S and the front surface of the substrates 10 face each other.

In the film forming chamber 19, the thin film forming nozzle 1R performs first direction mist spray treatment of spraying the source mist MT toward the left side (+Y direction) from the spray port provided in the spray surface 1S.

In the film forming chamber 19, the thin film forming nozzle 1L performs second direction mist spray treatment of spraying the source mist MT toward the right side (−Y direction) from the spray port provided in the spray surface 1S.

In this manner, the film forming apparatus 13 of the third embodiment includes the thin film forming nozzle 1R as a first direction mist spray unit and the thin film forming nozzle 1L as a second direction mist spray unit. Thus, in the film forming apparatus 13 of the third embodiment, the combination of the thin film forming nozzles 1R and 1L constitutes the mist spray unit, and the mist spray treatment includes a combination of the first direction mist spray treatment and the second direction mist spray treatment.

When the film forming chamber 19 performs mist spray treatment, the film forming chamber 19 can isolate the thin film forming nozzles 1R and 1L and the plurality of substrates 10 suspended by the substrate suspending parts 25p from the outside by closing the opening portions 99 between the right chamber 95 and the left chamber 96 with the air curtain 7.

Therefore, the film forming apparatus 13 of the third embodiment can set a film forming environment by closing both of the pair of opening portions 89 of the heating chamber 18 and the pair of opening portions 99 of the film forming chamber 19 with the air curtain 7 and moving the conveyor chain 25 along the conveying direction (X direction).

In the film forming apparatus 13 of the third embodiment, under the film forming environment, the infrared radiation apparatuses 2R and 2L and the thin film forming nozzles 1R and 1L are disposed separately from each other, so that the heating treatment performed for the substrates 10 in the heating chamber 18 and the mist spray treatment performed in the film forming chamber 19 are not affected by each other.

Then, in the film forming apparatus 13 of the third embodiment, under the film forming environment, the heating treatment of infrared radiation of the infrared radiation apparatuses 2R and 2L is performed for the substrates 10 in the heating chamber 18, and subsequently, the mist spray treatment of the thin film forming nozzles 1R and 1L is performed in the film forming chamber 901.

As a result, the film forming apparatus 13 of the third embodiment can form a thin film on each of the front surfaces and the back surfaces of the substrates 10 suspended from the conveyor chain 25 in the film forming chamber 901.

In this manner, similarly to the first embodiment, the film forming apparatus 13 of the third embodiment can heat the substrates 10 with the infrared radiation apparatuses 2R and 2L without touching the substrates 10. Therefore, the film forming apparatus 13 of the third embodiment can perform uniform heating without deforming the substrates 10, regardless of the shape of the substrates 10.

Further, similarly to the first embodiment, in the film forming apparatus 13, the infrared radiation apparatuses 2R and 2L and the thin film forming nozzles 1R and 1L are disposed separately from each other so that the heating treatment and the mist spray treatment are not affected by each other. Therefore, occurrence of the source mist evaporation phenomenon can be securely avoided when the mist spray treatment is performed.

As a result, similarly to the first embodiment, the film forming apparatus 13 of the third embodiment can form a thin film on the substrates 10 without reducing film forming quality and a film forming rate.

In addition, as the heating treatment performed for the substrates 10 in the heating chamber 18, the first direction heating treatment performed by the infrared radiation apparatus 2R and the second direction heating treatment performed by the infrared radiation apparatus 2L are simultaneously performed. This enables heating from the back surface of the substrates 10 in the first direction heating treatment and heating from the front surface of the substrates 10 in the second direction heating treatment.

As a result, similarly to the first embodiment, the film forming apparatus 13 of the third embodiment can more uniformly heat the substrates 10 in the heating chamber 80.

In addition, the film forming apparatus 13 of the third embodiment can form a thin film on each of the back surfaces and the front surfaces of the substrates by simultaneously performing the first direction mist spray treatment of the thin film forming nozzle 1R and the second direction mist spray treatment of the thin film forming nozzle 1L.

Further, by providing the infrared radiation apparatuses 2R and 2L being a heating mechanism outside the heating chamber 18, the film forming apparatus 13 of the third embodiment can simplify maintenance of the infrared radiation apparatuses 2R and 2L, such as replacement of the infrared lamps 22.

In addition, the heating chamber 18 of the film forming apparatus 13 of the third embodiment has, as its constituent material, quartz glass being an infrared light transmitting material having excellent transmittance for infrared light radiated from the infrared lamps 22 and 42.

This configuration produces an effect of reducing an infrared light absorption degree of the side surface of the right chamber 85 at the time of heating the substrates 10 through the side surface of the right chamber 85 of the heating chamber 18 in the first direction heating treatment to a minimum necessary degree. In a similar manner, the configuration produces an effect of reducing an infrared light absorption degree of the side surface of the left chamber 86 at the time of heating the substrates 10 through the side surface of the left chamber 86 of the heating chamber 18 in the second direction heating treatment to a minimum necessary degree.

Note that, in the present invention, each embodiment can be freely combined or each embodiment can be modified or omitted as appropriate within the scope of the invention.

While the invention has been shown and described in detail, the foregoing description is in all aspects illustrative and not restrictive. It is therefore understood that numerous unillustrated modifications and variations can be devised without departing from the scope of the invention.

### EXPLANATION OF REFERENCE SIGNS

1, 1R, 1L Thin film forming nozzle
2, 2R, 2L, 4 Infrared radiation apparatus
11-13, 12X, 12Y Film forming apparatus
18, 80, 801, 802, 811, 812, 821 Heating chamber
19, 90, 901, 902, 911, 921, 922 Film forming chamber
21, 41 Lamp placing table
22, 42 Infrared lamp
25 Conveyor chain
51 Roller
52 Belt
53 Conveyor
81, 83, 91 Upper chamber
82, 84, 92 Lower chamber
85, 95 Right chamber
86, 96 Left chamber
88, 89, 98, 99 Opening portion

1. A film forming apparatus comprising:
a substrate conveying unit configured to convey a substrate;
a heating mechanism including an infrared lamp and configured to perform heating treatment of heating said substrate by radiating infrared light from said infrared lamp; and
a mist spray unit configured to perform mist spray treatment of spraying source mist obtained by atomizing a source solution, wherein
said heating mechanism and said mist spray unit are separately disposed so that said heating treatment and said mist spray treatment are not affected by each other, and
a thin film is formed on a front surface of said substrate by performing said heating treatment with said heating mechanism and then performing said mist spray treatment with said mist spray unit without performing other treatment, while conveying said substrate with said substrate conveying unit.

2. The film forming apparatus according to claim 1, wherein
said heating mechanism includes first to n-th (n≥2) heating mechanisms being configured to perform first to n-th heating treatments, respectively, and said heating treatment includes said first to n-th heating treatments,
said mist spray unit includes first to n-th mist spray units being configured to perform first to n-th mist spray treatments, respectively, and said mist spray treatment includes said first to n-th mist spray treatments,
said first to n-th heating mechanisms and said first to n-th mist spray units are separately disposed from each other so that said first to n-th heating treatments and said first to n-th mist spray treatments are not affected by each other, and
said first to n-th heating treatments and said first to n-th mist spray treatments are alternately performed in order of first to n-th treatments.

3. The film forming apparatus according to claim 1, wherein
at least one configuration is set out of a first configuration in which said heating mechanism includes a plurality of heating mechanisms and a second configuration in which said mist spray unit includes a plurality of mist spray units,
in a case of said first configuration, said heating treatment is consecutively performed without performing said mist spray treatment in-between by at least two heating mechanisms out of said plurality of heating mechanisms, and
in a case of said second configuration, said mist spray treatment is consecutively performed without performing said heating treatment in-between by at least two mist spray units out of said plurality of mist spray units.

4. The film forming apparatus according to claim 1, wherein
said heating mechanism includes
a first direction heating unit being configured to perform first direction heating treatment of heating said substrate by radiating infrared light toward a first direction, and
a second direction heating unit being configured to perform second direction heating treatment of heating said substrate by radiating infrared light toward a second direction being a direction opposite to said first direction, and
said heating treatment includes said first direction heating treatment and said second direction heating treatment.

5. The film forming apparatus according to claim 4, wherein
said mist spray unit includes
a first direction mist spray unit being configured to perform first direction mist spray treatment of spraying said source mist toward said first direction, and
a second direction mist spray unit being configured to perform second direction mist spray treatment of spraying said source mist toward id second direction, and
said mist spray treatment includes said first direction mist spray treatment and said second direction mist spray treatment.

6. The film forming apparatus according to claim 4, wherein
said first direction is a direction from a back surface toward said front surface of said substrate, and
said second direction is a direction from said front surface toward said back surface of said substrate.

7. The film forming apparatus according to claim 1, further comprising:
a heating chamber configured to internally accommodate said substrate and said heating mechanism when said heating treatment is performed; and
a film forming chamber configured to internally accommodate said substrate and said mist spray unit when said mist spray treatment is performed.

8. The film forming apparatus according to claim 1, further comprising:
a heating chamber configured to internally accommodate said substrate when said heating treatment is performed; and
a film forming chamber configured to internally accommodate-aid substrate and said mist spray unit when said mist spray treatment is performed, wherein
said heating mechanism is disposed outside said heating chamber, and heats said substrate by through said heating chamber, and
said heating chamber has an infrared light transmitting material having excellent transmittance for infrared light radiated from said infrared lamp as a constituent material.
